(19) United States
(12) Patent Application Publication
(10) Pub. No.: US 2023/0212457 A1
(43) Pub. Date: Jul. 6, 2023

(54) COMPOSITION FOR THE SELECTIVE ETCHING OF SILICON

(71) Applicant: ENF TECHNOLOGY CO., LTD., Gyeonggi-do (KR)

(72) Inventors: Jeong Sik OH, Gyeonggi-do (KR); Tae Ho KIM, Gyeonggi-do (KR); Gi Young KIM, Gyeonggi-do (KR); Myung Ho LEE, Gyeonggi-do (KR); Myung Geun SONG, Gyeonggi-do (KR)

(21) Appl. No.: 18/077,499

(22) Filed: Dec. 8, 2022

(30) Foreign Application Priority Data
Dec. 30, 2021 (KR) 10-2021-0192264

(51) Int. Cl. C09K 13/08; H01L 21/311

(52) U.S. Cl. CPC C09K 13/08; H01L 21/31111

(57) ABSTRACT

The present invention relates to a composition for selectively etching silicon on a surface on which a metal film and silicon (Si) are exposed.

According to the present invention, it is possible to improve etch selectivity of silicon on the semiconductor surface on which the metal film and silicon are exposed.

### CROSS REFERENCE TO RELATED APPLICATIONS

This application claims the benefit of priority to Korean Patent Application No. 10-2021-0192264 filed on Dec. 30, 2021, incorporated herein by reference.

### TECHNICAL FIELD

The present invention relates to a composition for selectively etching silicon on a surface on which a metal film and silicon (Si) are exposed.

### BACKGROUND ART

Titanium nitride (TiN) and tungsten (W) are used as a representative plug metal in the semiconductor field.

However, in the case of an acidic etchant of silicon containing etching species such as hydrofluoric acid and oxidizing species such as nitric acid and sulfuric acid, there is a problem in that the defect rate increases because of the low selectivity of silicon with respect to the tungsten film in the bulk etching of silicon during the semiconductor manufacturing process. In particular, as a metal such as titanium nitride or tungsten is etched non-selectively, a defect may occur in a subsequent process such as the exposed lower pattern and a short circuit. This problem of the acidic etchant is a limiting factor in the application of the acidic etchant in processes such as semiconductor packaging and Through Silicon Via (TSV), NAND, and wafer thinning.

Therefore, it is necessary to study a composition that has a very low etch rate of the metal film and can selectively etch only silicon.

### DETAILED DESCRIPTION OF THE INVENTION

### Technical Problem

It is an object of the present invention to provide a composition having the improved etch selectivity of silicon to a metal film.

### Solution to Problem

In order to solve the above problems, the present invention provides a composition for selective etching of silicon, comprising:

a fluorine compound;

nitric acid;

acetic acid;

phosphoric acid; and

a cationic oligomer having a molecular weight of Mw 100 to 100,000.

According to one embodiment, the fluorine compound may comprise one or more of hydrofluoric acid, ammonium bifluoride, sodium fluoride, potassium fluoride, aluminum fluoride, fluoroboric acid, ammonium fluoride, sodium bifluoride, potassium bifluoride, and ammonium tetrafluoroborate.

According to one embodiment, the cationic oligomer may comprise one or more of polyethyleneimine, polyethylene polyamine, polyallylamine, polyvinylamine, amino-poly(ethylene glycol)-b-poly(ε-caprolactone), amine poly(ethylene glycol-block-poly(lactide-co-glycolide), poly(ethylene glycol) bis(amine), O-(2-aminoethyl)polyethylene glycol, poly(2-ethyl-2-oxazoline) α-methyl, ω-2-hydroxyethylamine terminated, [poly(L-lactide), amine terminated], [poly(N-isopropyl acrylamine), amine terminated], 4-arm-PEG-amine, PEI-bmPEG, PEI-PEG-PEI, methoxy polyoxyethylene glycol amine, poly(ethylene glycol) methyl ether amine, spermine, silane-PEG-NH₂, trimethylolpropane tris[poly(propylene glycol), amine terminated] ether, 11-azido-3,6,9-trioxaundecan-1-amine.

According to one embodiment, the cationic oligomer may comprise one or more of polyethyleneimine having a molecular weight of Mw 100 to 15,000, polyethylene polyamine having a molecular weight of Mw 100 to 3,000, and polyallylamine having a molecular weight of Mw 5,000 to 100,000.

According to one embodiment, the etch rate of silicon in the present invention may be 3 μm/min or more, and the etch selectivity of silicon to the metal film may be 100 or more.

According to other embodiment of the present invention, there is provided a method for preparing a composition for selective etching of silicon, comprising mixing

0.5 to 10% by weight of a fluorine compound;

15 to 55% by weight of nitric acid;

1 to 20% by weight of acetic acid;

5 to 15% by weight of phosphoric acid; and

0.001 to 10% by weight of a cationic oligomer having a molecular weight of Mw 100 to 100,000.

According to another embodiment of the present invention, there is provided a semiconductor device manufactured using the composition for selective etching of silicon as described above.

The specific details of other embodiments according to the present invention are included in the detailed description below.

### Effect of the Invention

According to the present invention, it is possible to improve etch selectivity of silicon from the semiconductor surface on which both of a metal film and silicon are exposed.

### BEST MODE FOR CARRYING OUT THE INVENTION

The present invention may have various modifications and various embodiments, and specific embodiments will be described in detail. However, it is not intended to limit the present invention to specific embodiments, and should be understood to include all modifications, equivalents, and substitutes included in the spirit and scope of the present invention. In describing the present invention, if it is determined that a detailed description of a related known technology may obscure the gist of the present invention, the detailed description thereof will be omitted.

As used herein, unless otherwise specified, the expression “to” in relation to a number is used as an expression including the corresponding numerical value. Specifically, for example, the expression “1 to 2” is meant to include all numbers between 1 and 2 as well as 1 and 2.

In a semiconductor, silicon is oxidized to a silicon oxide film by oxidizing species generated from an oxidizing agent and an auxiliary oxidizing agent. The oxidized silicon oxide film is etched by contact with an etchant. When etching silicon, it is necessary to consider the selective etching amount of silicon to the metal film in order to minimize defects in the lower pattern and wiring short circuit.

In the present invention, it is intended to improve the selective etching effect of silicon by controlling direct corrosion and galvanic corrosion to the metal film, for example, the metal film containing titanium nitride (TiN), tungsten (W), etc., by providing a specific combination of additives.

Hereinafter, the composition for the selective etching of silicon according to embodiments of the present invention will be described in more detail.

Specifically, the present invention provides a composition for selective etching of silicon, comprising:

a fluorine compound;

nitric acid;

acetic acid;

phosphoric acid; and

a cationic oligomer having a molecular weight of Mw 100 to 100,000.

According to one embodiment, the fluorine compound of the present invention, which is a compound that dissociates to generate F⁻ or HF²⁻ having strong affinity with silicon, serves to etch the silicon oxide film. The fluorine compound may comprise one or more of hydrofluoric acid (HF), ammonium bifluoride (ABF, NH₄HF₂), sodium fluoride (NaF), potassium fluoride (KF), aluminum fluoride (AlF₃), fluoroboric acid (HBF₄), ammonium fluoride (NH₄F), sodium bifluoride (NaHF₂), potassium bifluoride (KHF₂) and ammonium tetrafluoroborate (NH₄BF₄). Specifically, it may comprise one or more of hydrofluoric acid, ammonium fluoride, and ammonium bifluoride, for example.

The content of the fluorine compound may be from 0.5 to 10% by weight, for example 2% by weight or more, 4% by weight or more, 5% by weight or more, and 8% by weight or less, 7% by weight or less. Within this content range, it is suitable for etching the silicon film with respect to the metal film.

According to one embodiment, the metal film to be etched in the present invention may comprise one or more of tungsten (W), titanium nitride (TiN), titanium (Ti), gold (Au), molybdenum (Mo), nickel (Ni), palladium (Pd) and platinum (Pt), and specifically, it may include, for example, titanium nitride, tungsten, or a combination thereof.

The nitric acid of the present invention may serve as an oxidizing agent to oxidize silicon to etch silicon more effectively. The content of nitric acid may be 15 to 55% by weight, for example, 20% by weight or more, 30% by weight or more, 40% by weight or more, 50% by weight or more, and also, for example, 55% by weight or less.

The phosphoric acid of the present invention may serve as a viscosity controlling agent to control the viscosity. The content of phosphoric acid may include 5 to 15% by weight, for example, 6% by weight or more, 8% by weight or more, and for example, 13% by weight or less.

The acetic acid of the present invention may serve as a stabilizer to prevent the decomposition of nitric acid. The content of acetic acid may be 1 to 20% by weight, for example, 2% by weight or more, 3% by weight or more, and for example, 15% by weight or less, 10% by weight or less, 8% by weight or less, 6% by weight or less.

The cationic oligomer of the present invention serves to control selectivity to improve the etch selectivity of silicon to a metal film. The cationic oligomer may comprise one or more of polyethyleneimine, polyethylene polyamine, poly(allylamine), polyvinylamine, aminopoly(ethylene glycol)-b-poly(ε-caprolactone), amine poly(ethylene glycol-block-poly(lactide-co-glycolide), poly(ethylene glycol) bis(amine), O-(2-aminoethyl)polyethylene glycol, poly(2-ethyl-2-oxazoline) α-methyl, ω-2-hydroxyethylamine terminated, [poly(L-lactide), amine terminated], [poly(N-isopropyl acrylamine), amine terminated], 4-arm-PEG-amine, PEI-bmPEG, PEI-PEG-PEI, methoxy polyoxyethylene glycol amine, poly(ethylene glycol) methyl ether amine, spermine, silane-PEG-NH₂, trimethylolpropane tris[poly(propylene glycol), amine terminated] ether, and 11-azido-3,6,9-trioxaundecan-1-amine.

Specifically, for example, the cationic oligomer may comprise one or more of polyethyleneimine having a molecular weight of Mw 100 to 15,000, for example a molecular weight of Mw 300 to 13,000, for example a molecular weight of Mw 500 to 12,000, polyethylene polyamine having a molecular weight of Mw 100 to 3,000, for example a molecular weight of Mw 100 to 2,000, for example a molecular weight of Mw 100 to 1,000, and polyallylamine having a molecular weight of Mw 5,000 to 100,000, for example a molecular weight of Mw 10,000 to 80,000. In the molecular weight range as described above, the etch selectivity of silicon to the metal film may be effectively improved, and when the molecular weight of the cationic oligomer is too high, the etch rate of silicon may be reduced.

In addition, the content of the cationic oligomer may be 0.001 to 10% by weight, for example, 0.005% by weight or more, 0.01% by weight or more, or 0.03% by weight or more, and also, for example, 5% by weight or less, 3% by weight or less, 1% by weight or less, or 0.5% by weight or less.

The present invention can improve the selective etching amount of silicon to the metal film due to the inclusion of phosphoric acid and the cationic oligomer. In particular, the cationic oligomer can physically adsorb to the metal surface, thereby reducing the oxidation rate of the metal. As a result, it is possible to effectively improve the etch selectivity of silicon to the metal film by lowering the etch rate of the metal film.

According to one embodiment, when treating the substrate in which the metal film and silicon are simultaneously exposed on the surface according to the present invention, the etch rate of silicon may be 3 μm/min or more, 5 μm/min or more, for example 6 μm/min or more, or 7 μm/min or more, and for example, 30 μm/min or less, 20 μm/min or less, or 15 μm/min or less.

In addition, the etching selectivity Si/W of silicon (Si) to the metal film may be 100 or more. Specifically, the etching selectivity Si/W of silicon (Si) to the titanium nitride (TiN) film may be 50 or more, for example 60 or more, 80 or more, or 100 or more, and 500 or less, 400 or less, 300 or less, or 200 or less. In addition, the etching selectivity Si/W of silicon (Si) to the tungsten (W) film may be 100 or more, for example 200 or more, 300 or more, or 400 or more, and for example 2000 or less, 1500 or less, or 1300 or less.

According to one embodiment, the amount of water such that the total weight of the composition is 100% by weight may be contained in the composition. The water to be used is not particularly limited, but deionized water may be used. Preferably, deionized water having a specific resistance value of 18 MΩ/cm or more which indicates the degree of removal of ions in water, may be used.

According to one embodiment, the composition of the present invention may further comprise any additives used in a conventional etchant composition in order to improve etching performance. For example, it may further comprise one or more selected from the group consisting of a stabilizer, a surfactant, a chelating agent, an antioxidant, a corrosion inhibitor, and a mixture thereof.

The stabilizer may be an etching stabilizer and may be added in order to suppress the generation of side reactions or byproducts that may be accompanied by unnecessary reactions of the etchant composition or the object to be etched.

The surfactant may be additionally added for the purpose of improving wettability of the etchant composition, improving foam properties of the additive, and increasing solubility of other organic additives. The surfactant may be 1 or 2 or more selected from nonionic surfactants, anionic surfactants, cationic surfactants, and amphoteric surfactants, and may be added in an amount of 0.0005 to 5% by weight based on the total weight of the composition, preferably 0.001 to 2% by weight based on the total weight of the composition. When the content of the surfactant is less than 0.0005% by weight based on the total weight of the composition, no effect can be expected, and when the content of the surfactant exceeds 5% by weight, solubility problems may occur, or process problems may occur due to excessive foaming.

The chelating agent may be additionally added for the purpose of increasing the solubility of metal impurities of the etchant composition or forming a uniformly etched surface. The chelating agent may be added in an amount of 0.1 to 5% by weight based on the total weight of the composition, and may preferably be an organic acid having both of a carboxyl group and a hydroxyl group.

The antioxidant and the corrosion inhibitor may be added in order to protect metals or metallic compounds used as materials for semiconductor devices. The antioxidant and the corrosion inhibitor may be used without limitation as long as they are commonly used in the art. For example, it may include, but not limited to, an azole-based compound, and may be added in an amount of 0.01 to 10% by weight based on the total weight of the composition.

According to another embodiment of the present invention, there is provided a semiconductor device or semiconductor apparatus manufactured using the composition for selective etching of silicon as described above. In addition, it is possible to provide a method of manufacturing a semiconductor device or semiconductor apparatus using the composition for selective etching of silicon of the present invention.

The etching method using the etching composition of the present invention may be performed according to a conventional method, and is not particularly limited.

Hereinafter, embodiments of the present invention will be described in detail so that those of ordinary skilled in the art can easily carry out the present invention. However, the present invention may be embodied in several different forms and is not limited to the embodiments described herein.

### EXAMPLES AND COMPARATIVE EXAMPLES

Compositions for selective etching of silicon were prepared with the composition shown in Table 1. Each composition comprises the amount of water such that the total weight of the composition is 100% by weight.

TABLE 1

| | Content (wt %) | | | | | |
|---|---|---|---|---|---|---|
| | | | | | | Cationic oligomer |
| | | | | | | type-Molecular |
| | Fluoric | Nitric | Phosphoric | Acetic | Cationic | weight |
| | acid | acid | acid | acid | oligomer | (Mw) |
| Comparative | 6.8 | 52.0 | 0.0 | 4.8 | | |
| Example 1 | | | | | | |
| Comparative | 6.8 | 15.0 | 9.7 | 4.8 | | |
| Example 2 | | | | | | |
| Comparative | 1.0 | 52.0 | 9.7 | 4.8 | | |
| Example 3 | | | | | | |
| Comparative | 6.8 | 52.0 | 9.7 | 4.8 | | |
| Example 4 | | | | | | |
| Example 1 | 6.8 | 52.0 | 9.7 | 4.8 | 0.05 | PEI-600 |
| Example 2 | 6.8 | 52.0 | 9.7 | 4.8 | 0.1 | PEI-600 |
| Example 3 | 6.8 | 52.0 | 9.7 | 4.8 | 0.2 | PEI-600 |
| Example 4 | 6.8 | 52.0 | 9.7 | 4.8 | 0.1 | PEI-10000 |
| Example 5 | 6.8 | 52.0 | 9.7 | 4.8 | 0.2 | PEI-10000 |
| Example 6 | 6.8 | 52.0 | 9.7 | 4.8 | 0.05 | Polyethyene |
| | | | | | | polyamine, 300 |
| Example 7 | 6.8 | 52.0 | 9.7 | 4.8 | 0.1 | Polyethyene |
| | | | | | | polyamine, 300 |
| Example 8 | 6.8 | 52.0 | 9.7 | 4.8 | 0.2 | Polyethyene |
| | | | | | | polyamine, 300 |
| Example 9 | 6.8 | 52.0 | 9.7 | 4.8 | 0.1 | Polyethyene |
| | | | | | | polyamine, 600 |
| Example 10 | 6.8 | 52.0 | 9.7 | 4.8 | 0.2 | Polyethyene |
| | | | | | | polyamine, 600 |
| Example 11 | 6.8 | 52.0 | 9.7 | 4.8 | 0.05 | Poly(allylamine) |
| | | | | | | solution, 15000 |
| Example 12 | 6.8 | 52.0 | 9.7 | 4.8 | 0.1 | Poly(allylamine) |
| | | | | | | solution, 15000 |
| Example 13 | 6.8 | 52.0 | 9.7 | 4.8 | 0.2 | Poly(allylamine) |
| | | | | | | solution, 15000 |
| Example 14 | 6.8 | 52.0 | 9.7 | 4.8 | 0.1 | Poly(allylamine) |
| | | | | | | solution, 65000 |
| Example 15 | 6.8 | 52.0 | 9.7 | 4.8 | 0.2 | Poly(allylamine) |
| | | | | | | solution, 65000 |

### Experimental Example 1: Evaluation of Etch Rate

In order to determine the etch rate for each composition, the substrate to be evaluated having both titanium nitride (TiN) and silicon or both tungsten (W) and silicon exposed on the surface was cut to 20×20 mm, and the thickness and weight of each substrate were measured. The etchant composition according to each of Examples and Comparative Examples was introduced into a thermostat maintained at 25° C. and the substrate to be evaluated was immersed for 15 minutes to carry out the etching process. After the etching was completed, the substrate was washed with ultrapure water and then the remaining etchant composition and moisture were completely dried using a drying device. Then, the weight of the dried substrate was measured, the weight change before and after evaluation was calculated, and the etch rate was measured using Equation 1 below.

(Initial substrate thickness×weight reduction rate)/Processing time=Etch rate [Equation 1]

The results are shown in Table 2.

TABLE 2

| | Etch rate | | | Etch rate | |
|---|---|---|---|---|---|
| | (μm/min) | | Selectivity | (μm/min) | Selectivity |
| | Si | TiN | Si/TiN | W | Si/W |
| Comparative | 2.12 | 0.050 | 42 | 0.020 | 106 |
| Example 1 | | | | | |
| Comparative | 0.00 | 0.000 | 0 | 0.000 | 0 |
| Example 2 | | | | | |
| Comparative | 0.00 | 0.000 | 0 | 0.000 | 0 |
| Example 3 | | | | | |
| Comparative | 10.41 | 0.312 | 33 | 0.230 | 45 |
| Example 4 | | | | | |
| Example 1 | 10.05 | 0.094 | 107 | 0.020 | 503 |
| Example 2 | 10.09 | 0.053 | 190 | 0.013 | 776 |
| Example 3 | 10.03 | 0.037 | 271 | 0.012 | 836 |
| Example 4 | 10.01 | 0.077 | 130 | 0.014 | 715 |
| Example 5 | 10.01 | 0.032 | 313 | 0.013 | 770 |
| Example 6 | 10.22 | 0.088 | 116 | 0.019 | 538 |
| Example 7 | 10.13 | 0.049 | 207 | 0.012 | 844 |
| Example 8 | 10.01 | 0.033 | 303 | 0.011 | 910 |
| Example 9 | 10.19 | 0.076 | 134 | 0.009 | 1132 |
| Example 10 | 10.09 | 0.042 | 240 | 0.008 | 1261 |
| Example 11 | 10.19 | 0.101 | 101 | 0.027 | 377 |
| Example 12 | 10.08 | 0.077 | 131 | 0.021 | 480 |
| Example 13 | 10.01 | 0.064 | 156 | 0.017 | 589 |
| Example 14 | 9.22 | 0.069 | 134 | 0.016 | 576 |
| Example 15 | 7.64 | 0.047 | 163 | 0.011 | 695 |

As can be seen from Table 2, in the case of Comparative Examples, the etching of silicon was not sufficiently achieved. Specifically, it is confirmed that in Comparative Example 1 using the composition not containing phosphoric acid and cationic oligomer, the etch rate and the selectivity of silicon were low, in Comparative Examples 2 and 3 not containing cationic oligomer, etching was hardly achieved on both metal and silicon, and in Comparative Example 4, the selectivity was low due to the high etch rate of the metal film.

On the other hand, the results according to the examples confirmed that the etch rate of silicon was 7 μm/min or more, while the Si/TiN selectivity was 100 or more, and the Si/W selectivity was 300 or more. In particular, it is confirmed that in the case of Example 5 or 8 containing polyethyleneimine having a molecular weight of Mw 10,000 or polyethylene polyamine having a molecular weight of Mw 300, etch selectivity of Si/TiN is 300 or more, and in the case of Examples 8 to 10 containing polyethylene polyamine having a molecular weight of Mw 300 or Mw 600, etch selectivity of Si/W is excellent as 900 or more.

Therefore, the etchant composition according to the present invention improves the etch selectivity of silicon to the metal film effectively by reducing the etch rate of the metal film.

As described above, the specific parts of the present invention have been described in detail, and for those of ordinary skilled in the art to which the present invention pertains, it is clear that it is clear that these specific techniques merely describe a preferred embodiment and the scope of the present invention is not limited thereto. Those of ordinary skilled in the art to which the present invention pertains will be able to make various applications and modifications within the scope of the present invention based on the above contents. Accordingly, the substantial scope of the present invention will be defined by the appended claims and their equivalents.

What is claimed is:

1. A composition for selective etching of silicon, comprising:
a fluorine compound;
nitric acid;
acetic acid;
phosphoric acid; and
a cationic oligomer having a molecular weight of Mw 100 to 100,000.

2. The composition for selective etching of silicon according to claim 1, wherein the fluorine compound comprises one or more of hydrofluoric acid, ammonium bifluoride, sodium fluoride, potassium fluoride, aluminum fluoride, fluoroboric acid, ammonium fluoride, sodium bifluoride, potassium bifluoride, and ammonium tetrafluoroborate.

3. The composition for selective etching of silicon according to claim 1, wherein the cationic oligomer comprises one or more of polyethyleneimine, polyethylene polyamine, polyallylamine, polyvinylamine, amino-poly(ethylene glycol)-b-poly(ε-caprolactone), amine poly(ethylene glycol-block-poly(lactide-co-glycolide), poly(ethylene glycol) bis(amine), O-(2-aminoethyl)polyethylene glycol, poly(2-ethyl-2-oxazoline) α-methyl, ω-2-hydroxyethylamine terminated, [poly(L-lactide), amine terminated], [poly(N-isopropyl acrylamine), amine terminated], 4-arm-PEG-amine, PEI-bmPEG, PEI-PEG-PEI, methoxy polyoxyethylene glycol amine, poly(ethylene glycol) methyl ether amine, spermine, silane-PEG-NH₂, trimethylolpropane tris[poly(propylene glycol), amine terminated]ether, 11-azido-3,6,9-trioxaundecan-1-amine.

4. The composition for selective etching of silicon according to claim 1, wherein the cationic oligomer comprises one or more of polyethyleneimine having a molecular weight of Mw 100 to 15,000, polyethylene polyamine having a molecular weight of Mw 100 to 3,000, and polyallylamine having a molecular weight of Mw 5,000 to 100,000.

5. The composition for selective etching of silicon according to claim 1, wherein the etch rate of silicon is 3 μm/min or more, and the etch selectivity of silicon to the metal film is 100 or more.

6. A method for preparing a composition for selective etching of silicon, comprising mixing:
0.5 to 10% by weight of a fluorine compound;
15 to 55% by weight of nitric acid;
1 to 20% by weight of acetic acid;
5 to 15% by weight of phosphoric acid; and
0.001 to 10% by weight of a cationic oligomer having a molecular weight of Mw 100 to 100,000.

7. A semiconductor device manufactured using the composition for selective etching of silicon of claim 1.
